(19) United States
(12) Patent Application Publication
(10) Pub. No.: US 2024/0404870 A1
(43) Pub. Date: Dec. 5, 2024

(54) SEMICONDUCTOR DEVICE AND MANUFACTURING METHOD THEREOF

(71) Applicant: NANYA TECHNOLOGY CORPORATION, New Taipei city (TW)

(72) Inventors: Tsung-Cheng CHEN, Yilan County (TW); Ying-Cheng CHUANG, Taoyuan City (TW)

(21) Appl. No.: 18/203,763

(22) Filed: May 31, 2023

(51) Int. Cl. H01L 21/762; H01L 21/321; H10B 41/40; H10B 43/40

(52) U.S. Cl. CPC H01L 21/76224; H01L 21/3212; H10B 41/40; H10B 43/40

(57) ABSTRACT

A manufacturing method of a semiconductor device including providing a substrate, forming a hard mask over the substrate, etching the substrate by using the hard mask as an etch mask to form a first protrusion region and a plurality of second protrusion regions, wherein the first protrusion region is separated from a closest one of the second protrusion regions by a first trench, and neighboring two of the second protrusion regions are separated by a second trench, forming a first dielectric layer lining the first trench and the second trench, forming a second dielectric layer in the first trench, in which the second dielectric layer is along the first dielectric layer in the first trench, etching back the second dielectric layer to form a blocking structure, and filling the first trench with a filling material, in which the filling material covers the blocking structure.

### BACKGROUND

### Field of Disclosure

The present disclosure relates to a semiconductor device and a manufacturing method thereof.

### Description of Related Art

A memory device includes a memory cell region and a peripheral circuit region. The memory cell region includes a plurality of active areas separated by insulation structures. The active areas in the central regions should be protected and at proper locations to ensure that the memory device works properly.

### SUMMARY

Some embodiments of the present disclosure provides a manufacturing method of a semiconductor device including providing a semiconductor substrate, forming a hard mask over the semiconductor substrate, etching the semiconductor substrate by using the hard mask as an etch mask to form a first protrusion region and a plurality of second protrusion regions, wherein the first protrusion region is separated from a closest one of the second protrusion regions by a first trench, and neighboring two of the second protrusion regions are separated by a second trench, forming a first dielectric layer lining the first trench and the second trench, forming a second dielectric layer in the first trench, in which the second dielectric layer is along the first dielectric layer in the first trench, etching back the second dielectric layer to form a blocking structure, and filling the first trench with a filling material, in which the filling material covers the blocking structure.

In some embodiments, the method further includes forming a sacrificial layer over the second dielectric layer and filling the first trench with the sacrificial layer, performing a planarization process to the second dielectric layer and the sacrificial layer, so that an upper surface of the second dielectric layer and an upper surface of the sacrificial layer are leveled with an upper surface of the first dielectric layer, etching the second dielectric layer, so that a top of the second dielectric layer is below a bottom of the hard mask, and after etching back the second dielectric layer, the second dielectric layer becomes the blocking structure, and removing the sacrificial layer.

In some embodiments, the first dielectric layer is made of a first material, the second dielectric layer is made of a second material, and a dielectric constant of the first material is lower than a dielectric constant of the second material.

In some embodiments, the sacrificial layer is made of a third material, and the third material is different from the second material.

In some embodiments, filling the first trench with the filling material includes forming a filling material layer over an upper surface of the first dielectric layer and in the first trench, annealing the filling material layer to cure the filling material layer, and performing a chemical mechanical polish to remove a portion of the filling material layer and the first dielectric layer, so that the hard mask is exposed and the filling material is formed.

In some embodiments, the blocking structure expands during annealing the filling material layer and the filling material layer shrinks during annealing the filling material layer.

In some embodiments, etching back the blocking structure is performed such that a top end of the blocking structure is lower than a bottom of the hard mask and higher than upper surfaces of the second protrusion regions.

In some embodiments, the method further includes forming an oxide layer at an upper surface of the semiconductor substrate before forming the hard mask over the semiconductor substrate, in which etching back the blocking structure is performed such that a top end of the blocking structure is lower than an upper surface of the oxide layer and higher than a bottom of the oxide layer.

In some embodiments, the first trench is wider than the second opening.

Some embodiments of the present disclosure provides a manufacturing method of a semiconductor device including providing a semiconductor substrate, forming a hard mask over the semiconductor substrate, etching the semiconductor substrate by using the hard mask, in which the semiconductor substrate is divided into a central region and a peripheral region, and the central region and the peripheral region are separated by a first trench, forming a first dielectric layer along a sidewall of the semiconductor substrate in the first trench, forming a blocking structure in the first trench, wherein the blocking structure is in a U-shaped, and filling the first trench with a filling material, wherein the filling material covers the blocking structure and is in contact with the first dielectric layer.

In some embodiments, the method further includes forming an oxide layer at an upper surface of the semiconductor substrate before forming the hard mask over the semiconductor substrate.

In some embodiments, forming a blocking structure in the first trench includes forming a second dielectric layer along the first dielectric layer, forming a sacrificial layer over the second dielectric layer and filing the first trench with the sacrificial layer, performing a planarization process to the second dielectric layer and the sacrificial layer, so that an upper surface of the second dielectric layer and an upper surface of the sacrificial layer are leveled with an upper surface of the first dielectric layer, etching the second dielectric layer, so that a top of the second dielectric layer is lower than a bottom of the hard mask and higher than a bottom of the oxide layer, and the second dielectric layer becomes the blocking structure, and removing the sacrificial layer.

In some embodiments, a flowable chemical vapor deposition is performed to fill the first trench with the filling material.

In some embodiments, the filling material and the first dielectric layer are made of a first material, the blocking structure is made of a second material, a dielectric constant of the first material is lower than a dielectric constant of the second material.

In some embodiments, the method further includes removing the hard mask after filling the first trench with the filling material.

Some embodiments of the present disclosure provide a semiconductor device includes a semiconductor substrate and an isolation structure. The semiconductor substrate includes a central region and a peripheral region, and the central region includes a plurality of active areas, and the peripheral region is adjacent to the central region. The isolation structure is between the central region and the peripheral region of the semiconductor substrate, and the isolation structure includes a blocking structure and a first insulation structure. The blocking structure is in a U-shaped. The first insulation structure wraps the blocking structure. The insulation structure is made of a first material, the blocking structure is made of a second material, a dielectric constant of the first material is lower than a dielectric constant of the second material.

In some embodiments, the semiconductor device further includes an oxide layer over an upper surface of the semiconductor substrate, and a top of the blocking structure is higher than a bottom of the oxide layer and below a top of the oxide layer.

In some embodiments, the semiconductor device further includes a second insulation structure between the active areas.

In some embodiments, the second insulation structure is free of the second material.

In some embodiments, a bottom of the blocking structure of the isolation structure is lower than a bottom of the second insulation structure between the active areas.

Some embodiments of the present disclosure are related to methods of reducing the possibility of memory array toppling. Specifically, an isolation structure including a blocking structure is formed between a central region and a peripheral region of the memory structure. The blocking structure may be used to provide support for the active areas in the memory array, thereby preventing the active areas from toppling.

### BRIEF DESCRIPTION OF THE DRAWINGS

The disclosure can be more fully understood by reading the following detailed description of the embodiment, with reference made to the accompanying drawings as follows:

FIGS. 1-12 illustrate cross-section views of the manufacturing process of a semiconductor device in some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

Some embodiments of the present disclosure are related to methods of reducing the possibility of memory array toppling. Specifically, an isolation structure including a blocking structure is formed between a central region and a peripheral region of the memory structure. The blocking structure may be used to provide support for the active areas in the memory array, thereby preventing the active areas from toppling.

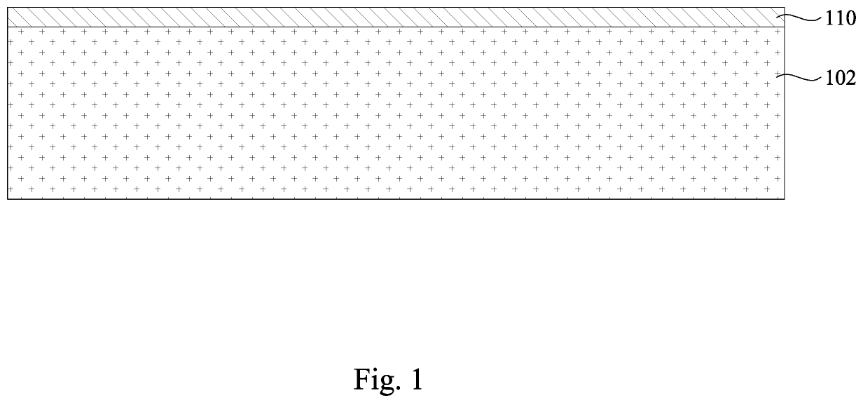

FIGS. 1-12 illustrate cross-section views of the manufacturing process of a semiconductor device 100 in some embodiments of the present disclosure. Referring to FIG. 1, a semiconductor substrate 102 is provided. In some embodiments, the semiconductor substrate 102 is made of silicon, and the semiconductor substrate 102 may be doped or may be doped in subsequent processes. Subsequently, an oxide layer 110 is formed at an upper surface of the semiconductor substrate 102. Specifically, the oxide layer 110 is thermally grown at the upper surface of the semiconductor substrate 102, and the oxide layer 110 may serve as a protection layer during doping the semiconductor substrate 102.

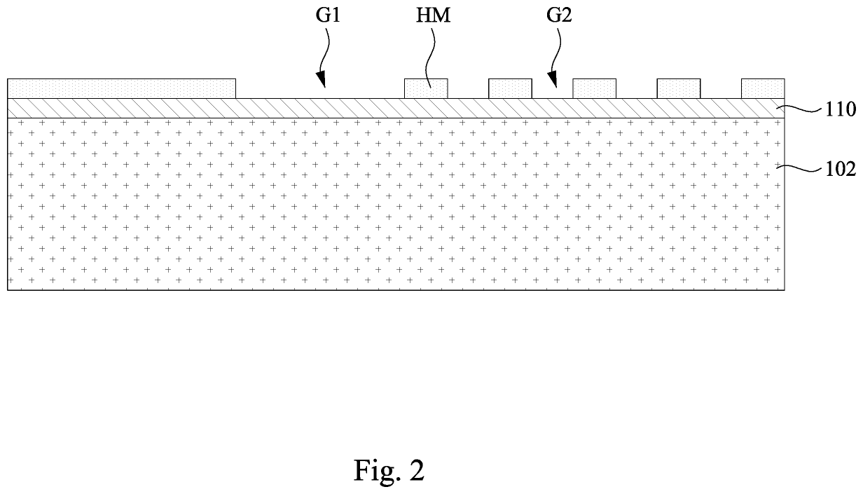

Referring to FIG. 2, a hard mask HM is formed over the semiconductor substrate 102 and the oxide layer 110. Specifically, a hard mask layer is first formed on the semiconductor substrate 102 and the oxide layer 110. A photoresist layer is formed on the hard mask layer and is exposed to an opaque pattern. The photoresist layer is then developed and is used to pattern the hard mask layer to form the hard mask HM. The hard mask HM includes a first gap G1 and a plurality of second gaps G2. The first gap G1 and the second gaps G2 expose the oxide layer 110, and the first gap G1 is wider than the second gap G2. In some embodiments, the hard mask HM is made of nitride.

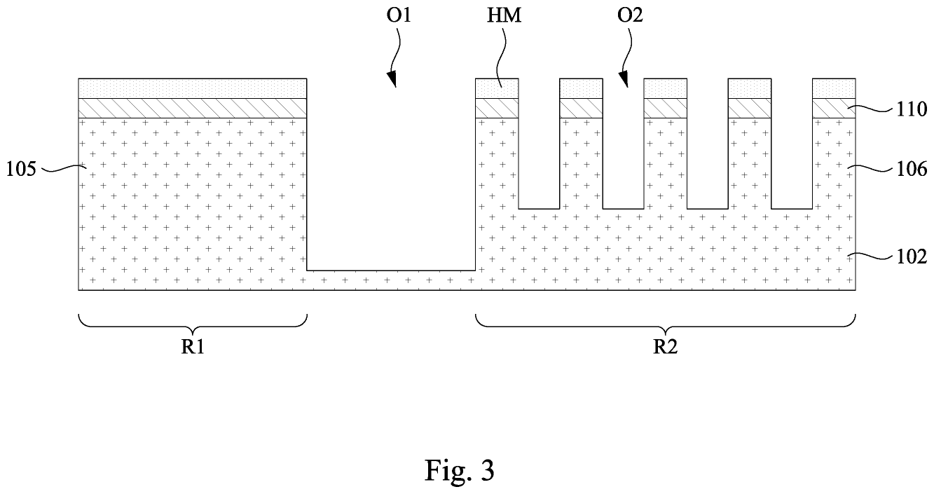

Referring to FIG. 3, the semiconductor substrate 102 is etched by using the hard mask HM as an etch mask to form a plurality of protrusion regions. As a result of the etching process, a trench O1 and a plurality of trenches O2 are formed in the semiconductor substrate 102, in which the trench O1 and the trenches O2 may inherit the patterns of the first gap G1 and the second gaps G2, respectively. A plurality of protrusion regions 106 are formed over the semiconductor substrate 102, in which each of the protrusion regions 106 is defined by two adjacent trenches O2, and neighboring two of the protrusion regions 106 are separated by the trench O2. In some embodiments, at least one of the protrusion regions 106 (e.g., the leftmost protrusion region 106 in FIG. 3) is defined by the trench O1 and a neighboring trench O2. On the other hand, a protrusion region 105 is formed over the semiconductor substrate 102, in which the protrusion region 105 is separated from a closest protrusion region 106 by the trench O1. In some embodiments, a width of the protrusion region 105 may be greater than a width of each protrusion region 106 in the cross-sectional view of FIG. 3.

Since the first gap G1 of the hard mask HM is wider than the second gap G2 of the hard mask HM, the trench O1 of the semiconductor substrate 102 is also wider than the trench O2 of the semiconductor substrate 102. In some embodiments, the bottom of the trench O1 is lower than the bottom of the trench O2. This is because during the etching process, the etchant may include a higher etching rate to the semiconductor substrate 102 through the wider first gap G1 of hard mask HM than through the narrower second gap G2 of the hard mask HM, which results in that the trench O1 is deeper than the trench O2 after the etching process is completed.

The semiconductor substrate 102 is divided into a central region R2 and a peripheral region R1, in which the protrusion regions 106 are located in the central region R2 and the protrusion region 105 is located in the peripheral region R1. The central region R2 and the peripheral region R1 are separated by the trench O1. In some embodiments, memory array may be formed over the central region R2 in subsequent processes, and peripheral circuit may be formed over the peripheral region R1 in subsequent processes. The oxide layer 110 is also etched by using the hard mask HM. In some embodiments, semiconductor devices (e.g., memory array and/or peripheral circuit) may be formed over the protrusion regions 105 and 106, and thus the protrusion regions 105 and 106 can also referred to as active regions.

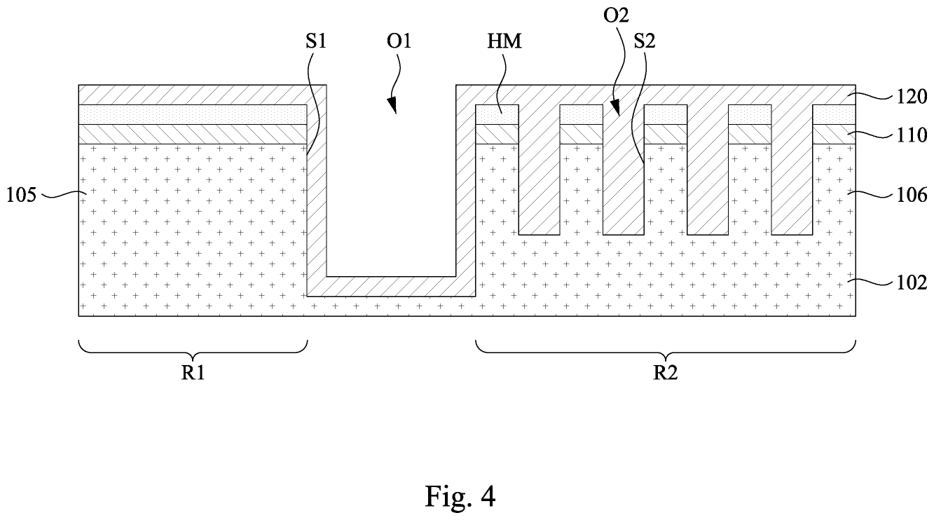

Referring to FIG. 4, a first dielectric layer 120 is deposited over the semiconductor substrate 102. In greater details, the first dielectric layer 120 is formed along a sidewall S1 of the trench O1 of the semiconductor substrate 102 and a sidewall S2 of the trench O2 of the semiconductor substrate 102. That is, the first dielectric layer 120 is formed lining the trench O1 and the trench O2. In some embodiments, the first dielectric layer 120 is further formed on the upper surface of the hard mask HM. In some embodiments, the first dielectric layer 120 is deposited over the semiconductor substrate 102 in a conformal manner. For example, the first dielectric layer 120 is conformal to the trench O1 of the semiconductor substrate 102. However, in some embodiments, the trench O2 may be too narrow and thus the first dielectric layer 120 may overfill the trenches O2. That is, an entirety of the trench O2 is filled with the first dielectric layer 120. In some embodiments, the first dielectric layer 120 at the bottom of the trench O1 is lower than the bottom of the first dielectric layer 120 in the trenches O2. In some embodiments, the first dielectric layer 120 may be made of oxides. In some embodiments, the first dielectric layer 120 is formed by atomic layer deposition (ALD), or the like.

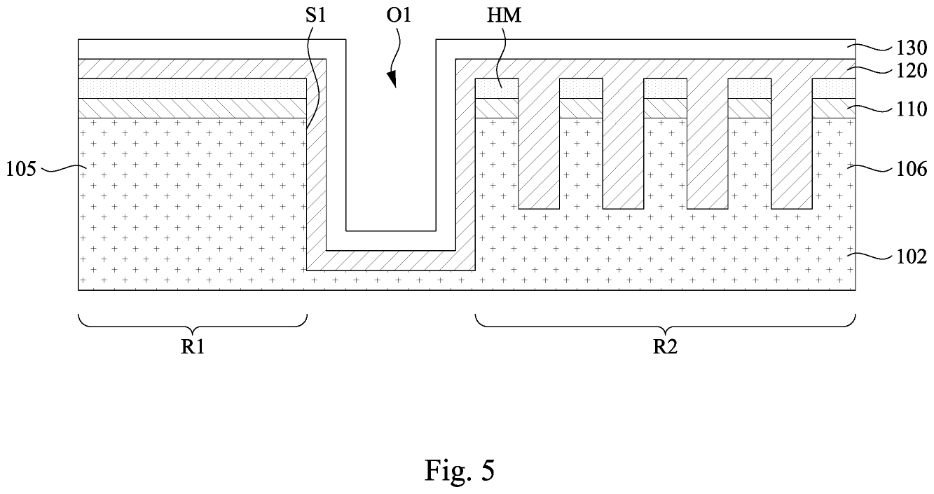

Referring to FIGS. 5-9, a blocking structure 150 is formed in the trench O1, wherein the blocking structure 150 is along the first dielectric layer 120 in the trench O1. Specifically, referring to FIG. 5, a second dielectric layer 130 is formed along the first dielectric layer 120. The second dielectric layer 130 is conformal to the first dielectric layer 120. That is, the second dielectric layer 130 is over the upper surface of the first dielectric layer 120 and is along the sidewall 51 of the semiconductor substrate 102 in the trench O1. The second dielectric layer 130 at the bottom of the trench O1 is lower than the bottom of the first dielectric layer 120 in the central region R2. The first dielectric layer 120 is made of a first material, the second dielectric layer 130 is made of a second material different from the first material. In some embodiments, if the first dielectric layer 120 is made of oxide, the second dielectric layer 130 may be made of nitrides. In some embodiments, the second dielectric layer 130 is formed by physical vapor deposition (PVD), chemical vapor deposition (CVD), atomic layer deposition (ALD), or the like.

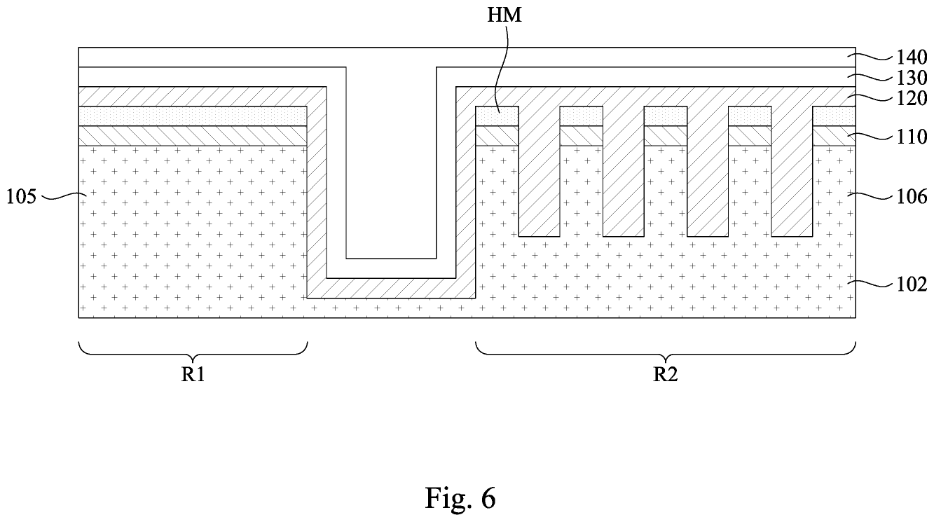

Referring to FIG. 6, a sacrificial layer 140 is formed over the second dielectric layer 130, and the trench O1 is filled with the sacrificial layer 140. The sacrificial layer 140 is made of a third material, and the third material is different from the second material and the first material. In some embodiments, the sacrificial layer 140 is made of organic material, such as photoresist underlayer. In some embodiments, the sacrificial layer 140 is formed by spin coating.

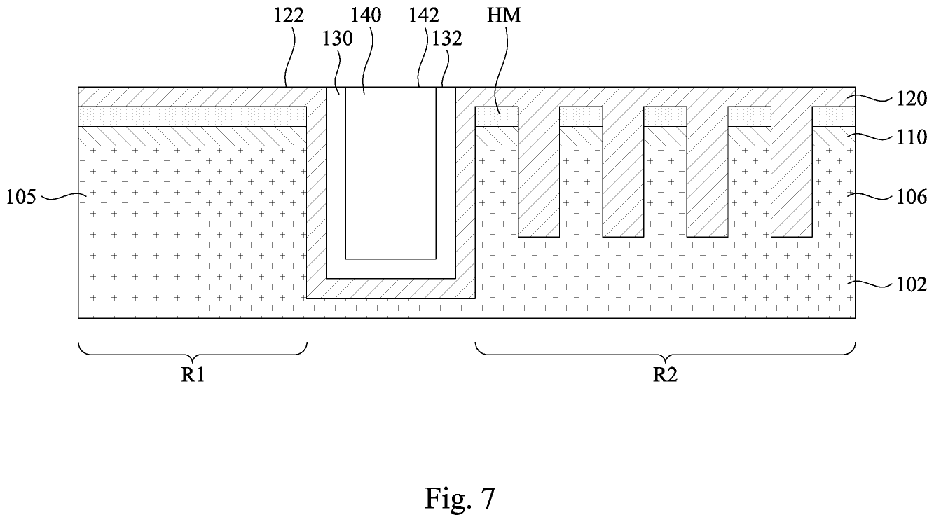

Referring to FIG. 7, a planarization process is performed to the second dielectric layer 130 and the sacrificial layer 140 to remove excess materials of the sacrificial layer 140 until the second dielectric layer 130 is exposed. During the planarization process, a portion of the second dielectric layer 130 and a portion of the sacrificial layer 140 are removed, so that an upper surface 132 of the second dielectric layer 130 and an upper surface 142 of the sacrificial layer 140 are substantially leveled with an upper surface 122 of the first dielectric layer 120. As such, the sacrificial layer 140 covers the bottom of the second dielectric layer 130 and exposes the portion of the second dielectric layer 130 protruding from the bottom of the second dielectric layer 130. In some embodiments, the first dielectric layer 120, the second dielectric layer 130 and the sacrificial layer 140 may be planarized by chemical mechanical polish (CMP).

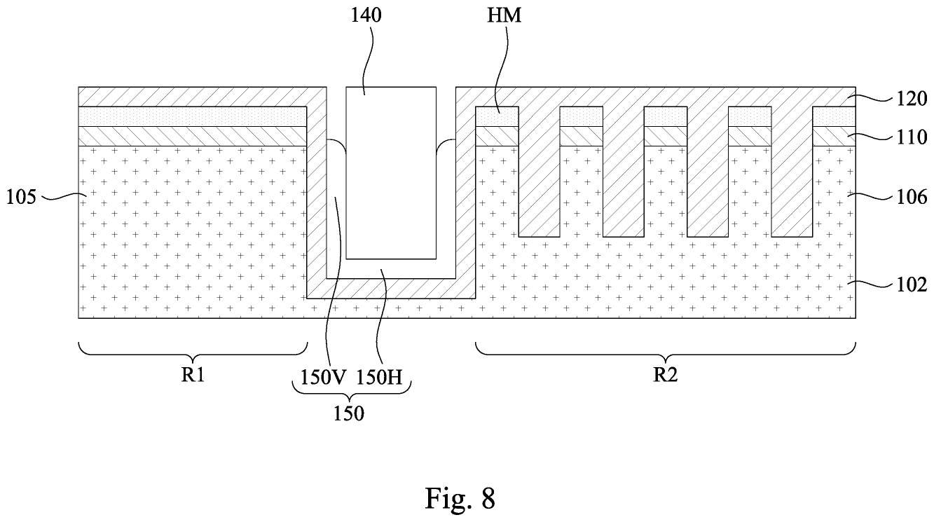

Referring to FIG. 8, the second dielectric layer 130 is etched back, so that a top of the second dielectric layer 130 is below a bottom of the hard mask HM, and the second dielectric layer 130 becomes the blocking structure 150. In some embodiments, the first material of the first dielectric layer 120 and the third material of the sacrificial layer 140 may include higher etching resistance to the etching process than the second material of the second dielectric layer 130, and thus the first dielectric layer 120 and the sacrificial layer 140 may keep substantially intact during etching the second dielectric layer 130. The sacrificial layer 140 serves as the mask to protect the bottom of the second dielectric layer 130 and exposes the portion of the second dielectric layer 130 protruding from the bottom of the second dielectric layer 130. Therefore, the portion of the second dielectric layer 130 protruding from the bottom of the second dielectric layer 130 is partially etched, and the bottom of the second dielectric layer 130 still remains. The top of the second dielectric layer 130 is etched to a suitable level to form the blocking structure 150, and the blocking structure 150 is in a U-shaped. For example, the blocking structure 150 may include a horizontal portion 150H and two vertical portions 150V extending upwardly from opposite ends of the horizontal portion 150H. The blocking structure 150 is used to provide support for the protrusion regions 106 and prevent the protrusion regions 106 from toppling. In some embodiments, the top end of the blocking structure 150 (e.g., the top ends of the vertical portions 150V) is lower than the bottom of the hard mask HM and higher than a bottom of the oxide layer 110 (or the upper surface of the protrusion region 106). If the top of the blocking structure 150 is higher than the bottom of the hard mask HM, the blocking structure 150 may be damaged during removing the hard mask HM in the subsequent process. If the top of the second dielectric layer 130 is too low, the blocking structure 150 may not provide sufficient support so that the protrusion regions 106 may easily topple. In some embodiments, the top surface of the horizontal portion 150H of the blocking structure 150 may be lower than the bottom surface of the portions of the first dielectric layer 120 within the trenches O2. In some embodiments, the second dielectric layer 130 is etched by dry etching.

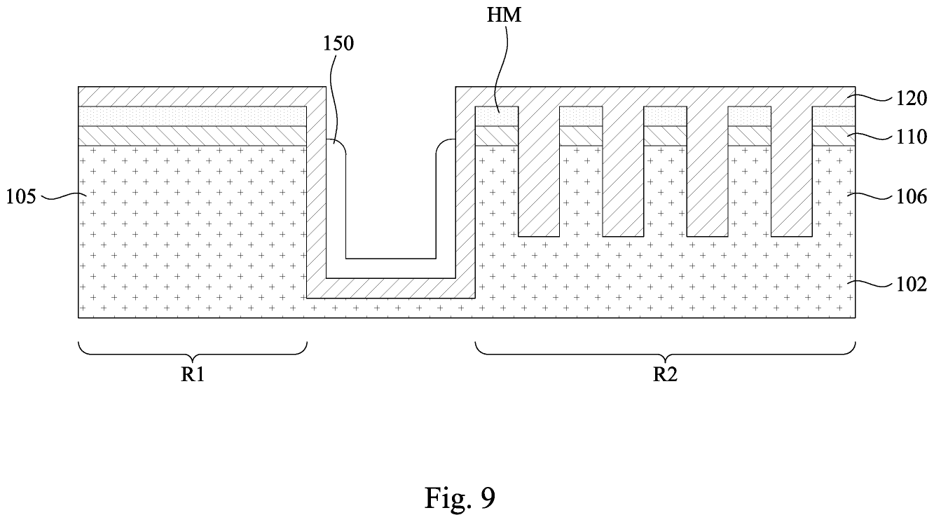

Referring to FIG. 9, the sacrificial layer 140 is removed, so that the bottom of the second dielectric layer 130 is exposed. In some embodiments, the sacrificial layer 140 is removed by ashing or stripping.

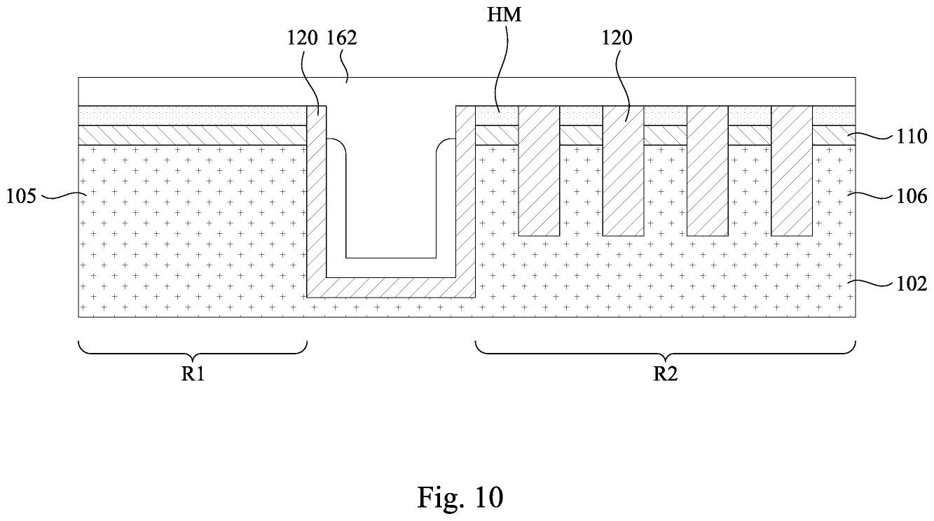

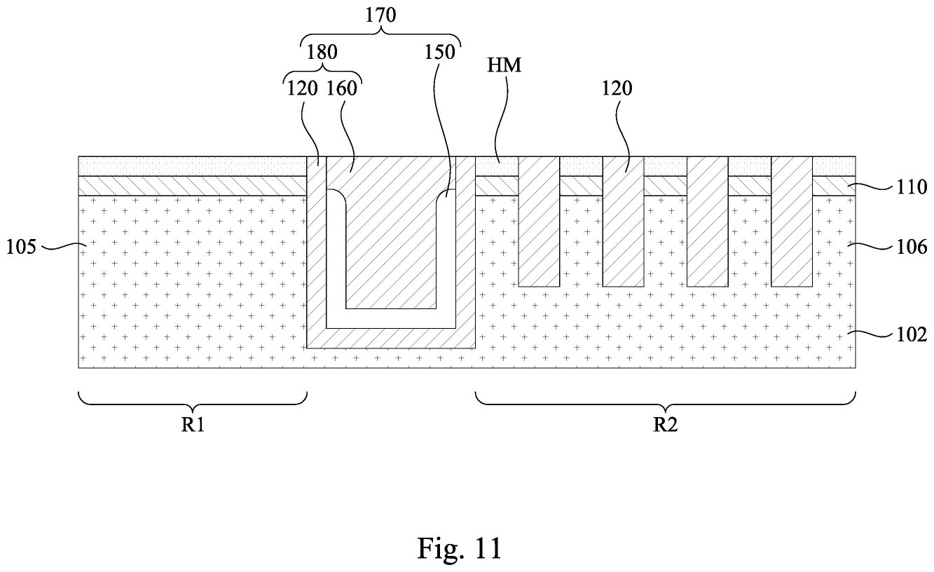

Referring to FIGS. 10 and 11, the trench O1 is filled with a filling material 160, wherein the filling material 160 covers the blocking structure 150 and is in contact with the first dielectric layer 120. The filling material 160 is made of the first material. That is, the filling material 160 and the first dielectric layer 120 are made of the same material. More specifically, referring to FIG. 10, a flowable chemical vapor deposition (FCVD) is performed to fill the first trench with a filling material layer 162. A filling material layer 162 may be first form over the upper surface of the first dielectric layer 120 and in the trench O1. The filling material layer 162 may be a flowable polymer layer, which is the precursor of forming the filling material 160, and then the filling material layer 162 is annealed at a high temperature to cure the filling material layer 162. Subsequently, referring to FIG. 11, a chemical mechanical polish is performed to remove a portion of the filling material layer 162 and the first dielectric layer 120, so that the hard mask HM is exposed and the filling material 160 is formed. The flowable chemical vapor deposition is performed at 35 degree Celsius to 80 degree Celsius. After the flowable chemical vapor deposition, the filling material 160 is annealed under a high temperature from 600 degree Celsius to 1000 degree Celsius. The filling material layer 162 tends to shrink during being annealed at the disclosed temperature. The shrinkage of the filling material layer 162 may cause the protrusion regions 106 topple if the blocking structure 150 and the first dielectric layer 120 are not presented. In such condition, the filling material layer 162 may be in contact with the protrusion region 106, and the shrunk filling material layer 162 may pull down the protrusion regions 106 during the annealing process. The blocking structure 150 is made of a low thermal expansion coefficient material, such that the blocking structure 150 shrinks less than the filling material layer 162 does during being annealed at the disclosed temperature. In some embodiments, the blocking structure 150 expands and the filling material layer 162 shrinks during annealing the filling material layer 162. Therefore, the blocking structure 150 may limit the shrinkage of the filling material layer 162, thereby preventing the protrusion regions 106 from toppling. Moreover, because the first dielectric layer 120 is formed by an ALD process rather than a FCVD process, there is no shrinkage issue to the first dielectric layer 120. Thus, the first dielectric layer 120 may also be beneficial to prevent the protrusion regions 106 from toppling. The filling material 160 and the first dielectric layer 120 may be viewed as an insulation structure 180. The first material of the insulation structure 180 is a better material for electrical isolation than the second material of the blocking structure 150, so the insulation structure 180 may provide good electrical isolation between the peripheral region R1 and the central region R2. For example, the dielectric constant of the first material (such as insulation structure 180) is lower than dielectric constant of the second material (such as blocking structure 150). In some embodiments, the remaining portion of the first dielectric layer 120 between the neighboring protrusion regions 106 can also be referred to as insulation structure.

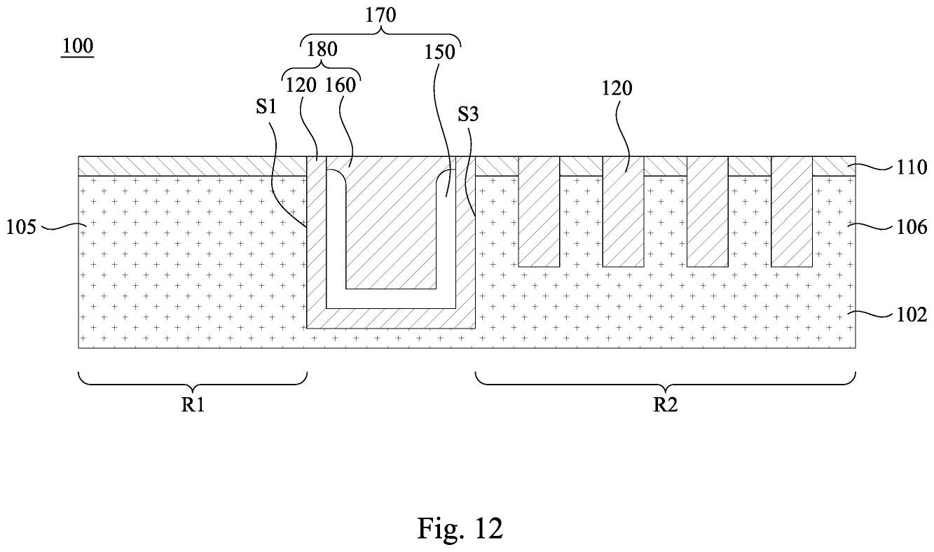

Referring to FIG. 12, the hard mask HM is removed after filling the trench O1 with the filling material 160. The oxide layer 110 is exposed accordingly. In some embodiments, the hard mask HM is removed by chemical mechanical polish. As such, the semiconductor device 100 is formed. The semiconductor device 100 is used in the memory device. Other components in the memory device may be formed in the subsequent processes. In some embodiments, regions between two adjacent protrusion portions 106 are free of the material of the blocking structure 150, because such regions are overfilled with the first dielectric layer 120 in the process of FIG. 4.

The semiconductor device 100 includes a semiconductor substrate 102 and an isolation structure 170. The semiconductor device 100 includes a central region R2 and a peripheral region R1. The central region R2 includes a plurality of active areas 106, and the peripheral region R1 is adjacent to the central region R2. The isolation structure 170 is between the central region R2 and the peripheral region R1 of the semiconductor substrate 102. The isolation structure 170 includes a blocking structure 150 and an insulation structure 180. The blocking structure 150 is in a U-shaped. The insulation structure 180 wraps the blocking structure 150, and the insulation structure 180 is in contact with the sidewall S3 of the central region R2. The top of the blocking structure 150 is not exposed. The insulation structure 180 is made of a first material, the blocking structure 150 is made of a second material, and a dielectric constant of the first material is lower than a dielectric constant of the second material. The blocking structure 150 made of the second material may be used to prevent the insulation structure 180 and the active areas 106 from toppling, and the insulation structure 180 made of first material is used prevent current leakage. In some embodiments, the insulation structure 180 is further between the active areas 106, and the bottom of the blocking structure 150 is lower than the bottom of the insulation structure 180 between the active areas 106.

The semiconductor device 100 further includes an oxide layer 110 over an upper surface of the semiconductor substrate 102, and a top of the blocking structure 150 is higher than a bottom of the oxide layer 110 and below a top of the oxide layer 110. Therefore, the blocking structure 150 provides sufficient support for the active areas 106.

As mentioned above, the isolation structure formed in the large opening between the central region and the peripheral region of the semiconductor device may be used to prevent the active areas in the central region from toppling. The isolation structure includes the blocking structure and the insulation structure. The material of the blocking structure shrinks less than the material of the insulation structure does at high temperature, or the material of the blocking structure expands high temperature. Therefore, the blocking structure may the active areas in the central region from toppling. The insulation structure may provide good electrical isolation between the peripheral region and the central region. Accordingly, the isolation structure may prevent current leakage and the active areas toppling at the same time.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A manufacturing method of a semiconductor device, comprising:
providing a semiconductor substrate;
forming a hard mask over the semiconductor substrate;
etching the semiconductor substrate by using the hard mask as an etch mask to form a first protrusion region and a plurality of second protrusion regions, wherein the first protrusion region is separated from a closest one of the second protrusion regions by a first trench, and neighboring two of the second protrusion regions are separated by a second trench;
forming a first dielectric layer lining the first trench and the second trench;
forming a second dielectric layer in the first trench, wherein the second dielectric layer is along the first dielectric layer in the first trench;
etching back the second dielectric layer to form a blocking structure; and
after etching back the second dielectric layer, filling the first trench with a filling material, wherein the filling material covers the blocking structure.

2. The manufacturing method of claim 1, further comprising:
forming a sacrificial layer over the second dielectric layer and filling the first trench with the sacrificial layer;
performing a planarization process to the second dielectric layer and the sacrificial layer, so that an upper surface of the second dielectric layer and an upper surface of the sacrificial layer are leveled with an upper surface of the first dielectric layer; and
after etching back the second dielectric layer, removing the sacrificial layer.

3. The manufacturing method of claim 2, wherein the filling material and the first dielectric layer are made of a first material, the second dielectric layer is made of a second material, a dielectric constant of the first material is lower than a dielectric constant of the second material.

4. The manufacturing method of claim 3, wherein the sacrificial layer is made of a third material, and the third material is different from the second material.

5. The manufacturing method of claim 1, wherein filling the first trench with the filling material comprises
forming a filling material layer over an upper surface of the first dielectric layer and in the first trench;
annealing the filling material layer to cure the filling material layer; and
performing a chemical mechanical polish to remove a portion of the filling material layer and the first dielectric layer, so that the hard mask is exposed and the filling material is formed.

6. The manufacturing method of claim 5, wherein the blocking structure expands during annealing the filling material layer and the filling material layer shrinks during annealing the filling material layer.

7. The manufacturing method of claim 1, wherein etching back the blocking structure is performed such that a top end of the blocking structure is lower than a bottom of the hard mask and higher than upper surfaces of the second protrusion regions.

8. The manufacturing method of claim 1, further comprising:
forming an oxide layer at an upper surface of the semiconductor substrate before forming the hard mask over the semiconductor substrate,
wherein etching back the blocking structure is performed such that a top end of the blocking structure is lower than an upper surface of the oxide layer and higher than a bottom of the oxide layer.

9. The manufacturing method of claim 1, wherein the first trench is wider than the second trench.

10. A manufacturing method of a semiconductor device, comprising:
providing a semiconductor substrate;
forming a hard mask over the semiconductor substrate;
etching the semiconductor substrate by using the hard mask as an etch mask, wherein the semiconductor substrate is divided into a central region and a peripheral region, and the central region and the peripheral region are separated by a first trench;
forming a first dielectric layer along a sidewall of the semiconductor substrate in the first trench;
forming a blocking structure in the first trench, wherein the blocking structure is in a U-shaped; and
filling the first trench with a filling material, wherein the filling material covers the blocking structure and is in contact with the first dielectric layer.

11. The manufacturing method of claim 10, further comprising:
forming an oxide layer at an upper surface of the semiconductor substrate before forming the hard mask over the semiconductor substrate.

12. The manufacturing method of claim 11, wherein forming the blocking structure in the first trench comprises:
forming a second dielectric layer along the first dielectric layer;
forming a sacrificial layer over the second dielectric layer and filing the first trench;
performing a planarization process to the second dielectric layer and the sacrificial layer, so that an upper surface of the second dielectric layer and an upper surface of the sacrificial layer are leveled with an upper surface of the first dielectric layer;
etching the second dielectric layer, so that a top of the second dielectric layer is lower than a bottom of the hard mask and higher than a bottom of the oxide layer, and the second dielectric layer becomes the blocking structure; and
removing the sacrificial layer.

13. The manufacturing method of claim 10, wherein a flowable chemical vapor deposition is performed to fill the first trench with the filling material.

14. The manufacturing method of claim 13, wherein the filling material and the first dielectric layer are made of a first material, the blocking structure is made of a second material, a dielectric constant of the first material is lower than a dielectric constant of the second material.

15. The manufacturing method of claim 10, further comprising:
removing the hard mask after filling the first trench with the filling material.

16. A semiconductor device, comprising:
a semiconductor substrate comprising a central region and a peripheral region, wherein the central region comprises a plurality of active areas, and the peripheral region is adjacent to the central region; and
an isolation structure between the central region and the peripheral region of the semiconductor substrate, wherein the isolation structure comprises:
a blocking structure, wherein the blocking structure is in a U-shaped; and
a first insulation structure wrapping the blocking structure, wherein the first insulation structure is made of a first material, the blocking structure is made of a second material, a dielectric constant of the first material is lower than a dielectric constant of the second material.

17. The semiconductor device of claim 16, further comprising:
an oxide layer over an upper surface of the semiconductor substrate, wherein a top of the blocking structure is higher than a bottom of the oxide layer and below a top of the oxide layer.

18. The semiconductor device of claim 16, further comprising a second insulation structure between the active areas.

19. The semiconductor device of claim 18, wherein the second insulation structure is free of the second material.

20. The semiconductor device of claim 18, wherein a bottom of the blocking structure of the isolation structure is lower than a bottom of the second insulation structure between the active areas.
